(19) United States
(12) Patent Application Publication
(10) Pub. No.: US 2025/0031547 A1
(43) Pub. Date: Jan. 23, 2025

(54) DISPLAY UNIT

(71) Applicant: TOPPAN HOLDINGS INC., Tokyo (JP)

(72) Inventor: Hiroki NAGATOME, Taito-ku (JP)

(73) Assignee: TOPPAN HOLDINGS INC., Tokyo (JP)

(21) Appl. No.: 18/910,480

(22) Filed: Oct. 9, 2024

Related U.S. Application Data
(63) Continuation of application No. PCT/JP2023/014028, filed on Apr. 5, 2023.

(30) Foreign Application Priority Data
Apr. 11, 2022 (JP) 2022-065160

(51) Int. Cl. H10K 59/38; H10K 59/80

(52) U.S. Cl. CPC H10K 59/38; H10K 59/879

(57) ABSTRACT

A display unit includes a device substrate on which light sources are disposed, a protective layer provided on the device substrate to cover the light sources; a color filter provided on the protective layer, the color filter including monochromatic filters disposed corresponding to the light sources, a lens array provided on the color filter, the lens array including microlenses disposed corresponding to the monochromatic filters, and a flattening layer provided on the lens array to cover the microlenses (41), the flattening layer having a refractive index lower than a refractive index of the microlenses. A refractive index nₘ of the microlenses, a refractive index nₜ of the flattening layer, and a ratio r/H between a curvature radius r and a height H of a lens surface of the microlenses satisfy a predetermined expression.

### CROSS-REFERENCE TO RELATED APPLICATIONS

The present application is a continuation of and claims the benefit of priority to International Application No. PCT/JP2023/014028, filed Apr. 5, 2023, which is based upon and claims the benefit of priority to Japanese Application No. 2022-065160, filed Apr. 11, 2022. The entire contents of these applications are incorporated herein by reference.

### BACKGROUND OF THE INVENTION

### Field of the Invention

The present invention relates to a display unit.

### Description of Background Art

JP 2021-136208 A describes a semispherical microlens disposed on a light-emitting device to enhance light-usage efficiency. Moreover, J P 2020-184481 A describes a translucent layer provided on a microlens to improve viewing angle characteristics. The entire contents of these publications are incorporated herein by reference.

### SUMMARY OF THE INVENTION

According to one aspect of the present invention, a display unit includes a device substrate, light sources positioned on the device substrate, a protective layer formed on the device substrate such that the protective layer is covering the light sources, a color filter formed on the protective layer and including monochromatic filters positioned corresponding to the light sources, respectively, a lens array formed on the color filter and including microlenses positioned corresponding to the monochromatic filters of the color filter, respectively, and a flattening layer formed on the lens array such that the flattening layer is covering the microlenses and has a refractive index that is lower than a refractive index of the microlenses. A ratio r/H between a curvature radius r and a height H of a lens surface of the microlenses satisfy 0.3<(nₘ−nₜ)−0.1(r/H)²+0.2(r/H)<0.6 where nₘ is the refractive index of the microlenses, and n, is the refractive index of the flattening layer.

According to another aspect of the present invention, a display unit includes a device substrate, light sources positioned on the device substrate, a protective layer formed on the device substrate such that the protective layer is covering the light sources, a color filter formed on the protective layer and including monochromatic filters positioned corresponding to the light sources, respectively, a lens array formed on the color filter and including microlenses positioned corresponding to the monochromatic filters of the color filter, respectively, and a flattening layer formed on the lens array such that the flattening layer is covering the microlenses and has a refractive index that is lower than a refractive index of the microlenses. A ratio r/H between a curvature radius r and a height H of a lens surface of the microlenses is 3 or greater, and a difference between a refractive index nₘ of the microlenses and a refractive index nₜ of the flattening layer is 0.3 or greater.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view illustrating a part of a display unit according to an embodiment of the present invention;

FIG. 2 is a diagram illustrating a positional relationship between an organic EL device, a color filter, and a microlens in plan view of the display unit;

FIG. 3 is a diagram illustrating a result of ray-trace simulation for a shape of microlenses;

FIG. 4 is a diagram illustrating a result of ray-trace simulation for another shape of microlenses;

FIG. 5 is a diagram illustrating a result of ray-trace simulation for another shape of microlenses; and

FIG. 6 is a schematic cross-sectional view illustrating a part of a display unit according to a modification example of an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

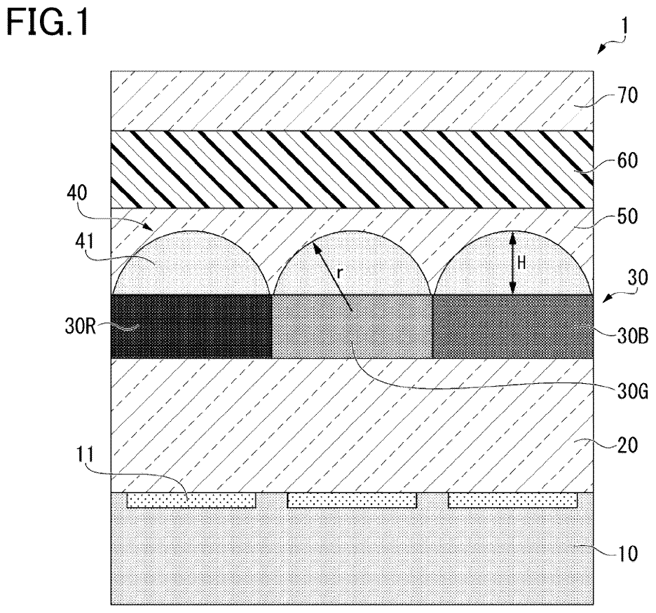

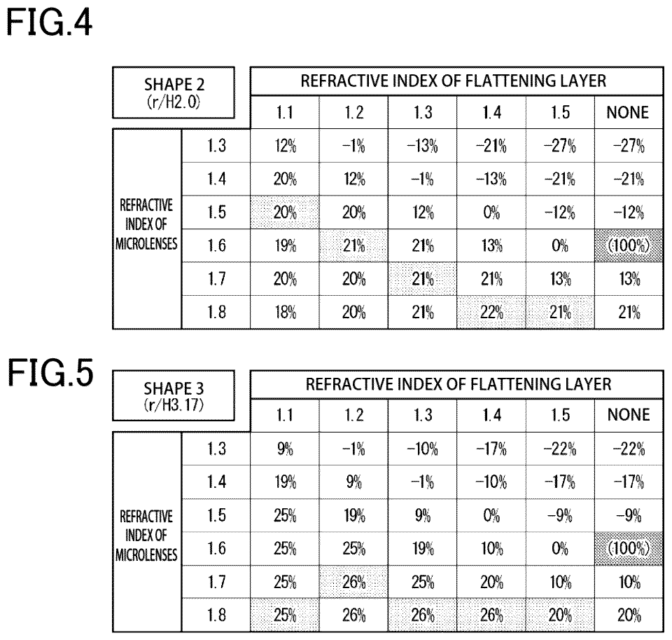

Description will be given below of an embodiment of the present invention with reference to FIG. 1 to FIG. 5. A display unit 1 according to an embodiment of the present invention includes organic EL devices 11 as light sources and has a configuration in which a large number of pixels are formed in front view.

FIG. 1 illustrates a schematic cross-sectional view of a part of the display unit 1 corresponding to one pixel. The display unit 1 includes a device substrate 10 on which the organic EL devices (light sources) 11 are disposed and a protective layer 20, a color filter 30, a lens array 40, and a flattening layer 50, which are formed on the device substrate 10. A translucent substrate 70 is bonded to the flattening layer 50 via an adhesive layer 60, and a user can see an image displayed by the display unit 1 through the translucent substrate 70.

The organic EL devices 11, which have a configuration including a pixel electrode, a common electrode, and a functional layer, are connected to non-illustrated wiring provided on the device substrate 10 and to be each independently driven for emission.

The protective layer 20, which is transparent, protects the organic EL devices 11 and achieves flattening to facilitate the installation of the color filter 30. The protective layer 20 may be formed of multiple layers and have gas-barrier properties.

A partition may be formed in the protective layer 20 to define a sub-pixel. The formation of the partition makes it possible to reduce stray light entering adjacent sub-pixels.

The color filter 30 is provided on the respective organic EL devices 11. The color filter 30 includes multiple monochromatic filters 30R, 30G and 30B that transmit light in a wavelength band of one of three primary colors of light, red (R), green (G) and blue (B), respectively. The number of the monochromatic filters and the colors of light passing therethrough may be determined in accordance with the display performance or the like of the display unit and yellow or the like may be included. The monochromatic filters 30R, 30G and 30B are disposed to overlap with the organic EL devices 11 in plan view. This is occasionally referred to as the monochromatic filters 30R, 30G and 30B being disposed corresponding to the respective organic EL devices 11.

The lens array 40 is formed on the color filter 30 and includes multiple microlenses 41 arrayed corresponding to the respective monochromatic filters 30R, 30G and 30B of the color filter 30. Here, the microlenses 41 being arrayed corresponding to the respective monochromatic filters 30R, 30G and 30B of the color filter 30 means the microlenses 41 being arrayed to overlap with the respective monochromatic filters 30R, 30G and 30B of the color filter 30 in plan view.

The microlenses 41 according to the present embodiment, which are so-called plano-convex lenses, have refractive indexes higher than at least refractive indexes of air and the flattening layer 50. Here, the microlenses 41 may be considered to each have the same refractive index.

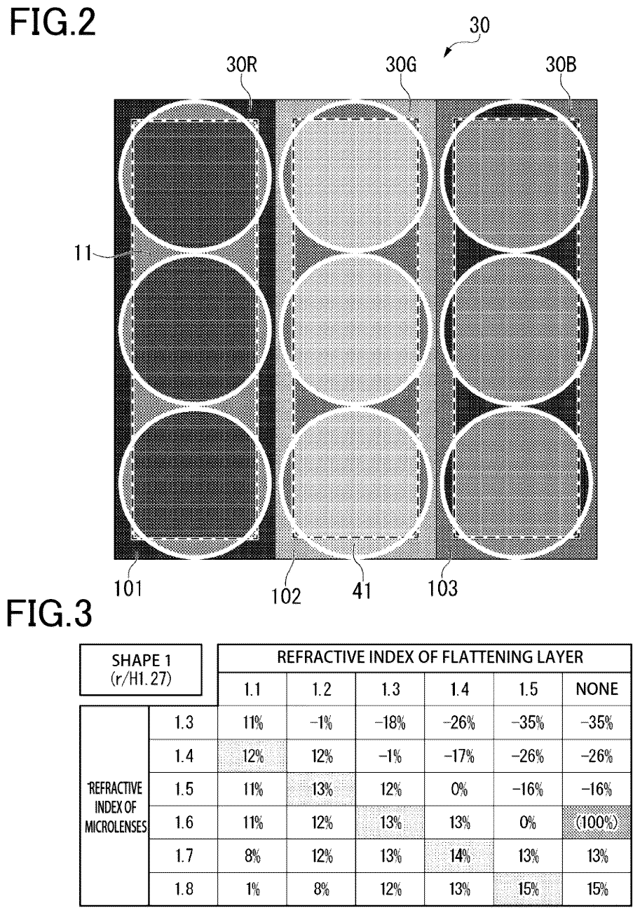

FIG. 2 illustrates a positional relationship between the organic EL devices 11, the color filter 30, and the microlenses 41 in plan view of a range illustrated in FIG. 1.

A pixel of the display unit 1 includes three sub-pixels 101, 102 and 103 corresponding to red (R), green (G) and blue (B), respectively. The red monochromatic filter 30R, the green monochromatic filter 30G, and the blue monochromatic filter 30B, which form the color filter 30, are disposed for the sub-pixels 101, 102 and 103, respectively. One of the organic EL devices 11 and three of the microlenses 41 are disposed for each of the sub-pixels 101, 102 and 103.

The above is merely by way of example and a shape of the sub-pixels in plan view and the numbers of organic EL devices 11 and the microlenses 41 disposed, and the like may be determined in accordance with the display performance or the like.

The flattening layer 50 absorbs unevenness of the microlenses 41 to achieve flattening, which facilitates bonding of the translucent substrate 70. Accordingly, a maximum thickness of the flattening layer 50 is equal to or greater than a height of the microlenses 41.

The flattening layer 50 has a refractive index lower than the refractive index of the microlenses 41. The closer the refractive index of the flattening layer 50 is to the refractive index of air, the greater the difference in refractive index between the flattening layer 50 and the microlenses 41.

The flattening layer 50 contains, by way of example, a hollow filler and a medium. The hollow filler and the medium are transparent at visible wavelengths and have, for example, a 90% or more total light transmissivity to light at visible wavelengths.

The hollow filler contributes to reducing the refractive index of the flattening layer 50. The medium intervenes between particles of the hollow filler to couple the hollow filler particles, which stabilizes the flattening layer 50.

A suitable material of the hollow filler can be exemplified by silicon dioxide (silica, SiO₂). A hollow filler including silica is inexpensive and has high transparency to visible wavelengths and physical stability. By virtue of the hollow filler contained in a low-refractive-index layer, air regions are scattered in the flattening layer 50, resulting in a decrease in the refractive index of the flattening layer 50, and the refractive index approaches a value of that of air with an increase in the content of the hollow filler.

In the display unit 1, light emitted from the driven organic EL devices 11 enters the microlenses 41 through the protective layer 20 and the color filter 30, and is extracted outside through the flattening layer 50, the adhesive layer 60, and the translucent substrate 70.

During the above-described process, light is also refracted at an interface between upper surfaces (lens surfaces) of the microlenses 41 and the flattening layer 50. Since the refraction varies with a shape of the lens surfaces and the refractive indexes of the microlenses 41 and the flattening layer 50, a study is conducted to efficiently extract light using a ray-trace simulation.

A model used for the simulation is as follows.

### Fixed Parameters

The shape of the microlenses 41: semispherical
Pitch PD between pixels (gaps): 2.8 μm
The thickness of the flattening layer 50: 1.2 μm
Distance DH between the organic EL device 11 and the microlenses 41: 2.6 μm

### Variable Parameters

The shape of the microlenses 41
   Shape 1
   Height H: 1.1 μm, curvature radius r of the lens surface: 1.4 μm (r/H 1.27) Shape 2
   Height H: 0.8 μm, curvature radius r of the lens surface: 1.6 μm (r/H 2.0) Shape 3
   Height H: 0.6 μm, curvature radius r of the lens surface: 1.9 μm (r/H 3.17)
   Refractive index of microlenses 41: in increments of 0.1 from 1.3 to 1.8, refractive index of the flattening layer 50: in increments of 0.1 from 1.1 to 1.5, and no flattening layer 50 (the adhesive layer 60 (refractive index 1.7) was disposed on the lens array 40)

Under the above-described conditions, the refractive index of the microlenses 41 was changed in increments of 0.1 and a brightness in a front direction of the pixel was calculated. Further, for each of Shapes 1 to 3 of the microlenses 41, a rate of improvement or a rate of decrease in brightness was calculated with reference to a brightness under the conditions of “the refractive index of the microlenses 41 being 1.6, no flattening layer 50.”

FIG. 3 to FIG. 5 illustrate simulation results of Shapes 1 to 3, respectively. For example, FIG. 3 shows that at the refractive index of the flattening layer 50 of 1.1 and the refractive index of the microlenses 41 of 1.3, the brightness was improved by 11% relative to the reference brightness. FIG. 3 also shows that at the refractive index of the flattening layer 50 of 1.5 and the refractive index of the microlenses 41 of 1.3, the brightness decreased by 35% relative to the reference brightness.

While it has been demonstrated that the brightness tends to be improved relative to the reference by reducing the refractive index of the flattening layer 50 to be lower than the refractive index of the microlenses 41 irrespective of the shape, totally unexpected findings were obtained that an excessively low refractive index of the flattening layer or an excessively high refractive index of the microlenses 41 leads to a decrease in effect in improving the brightness, an optimal range of the difference in refractive index therebetween varies with the shape, and the like.

Specifically, it has been found that a value of the difference in refractive index at which the brightness improvement effect is maximized tends to increase with a decrease in the height of the microlenses 41 and an increase in the curvature radius of the lens surfaces, that is, an increase in the value of r/H. In this study, an optimal difference in refractive index for Shape 1 was 0.3, whereas optimal differences in refractive index for Shapes 2 and 3, which were 0.4 and 0.5, respectively, changed in parallel with the values of r/H. It has also been found that a substantially favorable brightness improvement effect is obtained as long as the difference in refractive index falls within a range of +0.1 relative to the above-described optimal difference in refractive index irrespective of the shape.

For the display unit, dimensions of the microlenses 41 are variously changed in accordance with a pixel dimension or the like. It has been found that a favorable brightness improvement effect is obtained in a case where an inequality expression (1) below is satisfied.

$$0.3 < ( {n}_{m} - {n}_{t} ) - 0.1 {( r / H )}^{2} + 0.2 ( r / H ) < 0.6 \qquad ( 1 )$$

In the expression (1), nₘ denotes the refractive index of the microlenses 41 and nₜ denotes the refractive index of the flattening layer 50.

In this study, for Shape 1 with r/H in a range of 1 or greater and less than 2, a preferred range of the difference in refractive index was 0.2 or greater and 0.5 or less, and more preferably 0.2 or greater and 0.4 or less. For Shape 2 with r/H in a range of 2 or greater and less than 3, a preferred range of the difference in refractive index was 0.3 or greater and 0.6 or less, and more preferably 0.3 or greater and 0.5 or less. For Shape 3 with r/H in a range of 3 or greater, a preferred range of the difference in refractive index was 0.3 or greater, and more preferably 0.6 or greater and 0.8 or less. The respective conditions for the shapes all satisfy the expression (1) above.

In the display unit 1 according to the present embodiment, the refractive indexes of the microlenses 41 and the flattening layer 50 and the shape of the microlenses 41 are set so as to satisfy the expression (1) above on the basis of the above-described findings, which makes it possible to reduce a loss of outputted light even from light sources that are not so high in directionality, such as the organic EL devices 11, to improve the usage efficiency. As a result, it is possible to efficiently guide light generated from the organic EL devices 11 to the front of the unit irrespective of the pixel dimension or the like to significantly improve display quality such as brightness.

In the foregoing, an embodiment of the present invention is described in detail but the present invention is not limited to a specific embodiment and include alterations, combinations, and the like of the configurations within a range not departing from the scope of the present invention. Some of the alterations are described by way of example below but any other alternation is also possible. Two or more of the alterations may be combined as appropriate.

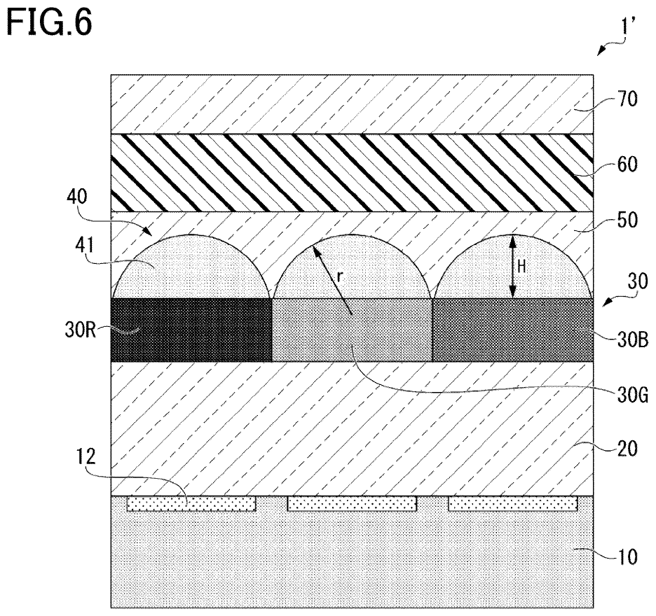

In a display unit according to an embodiment of the present invention, the light sources are not limited to the above-described organic EL devices 11 and may be micro LEDs 12 illustrated in FIG. 6 or any other light source device. FIG. 6 illustrates a display unit 1′ according to a modification example of an embodiment of the present invention. FIG. 6, in which the same member as that of the display unit 1 according to an embodiment of the present invention is labeled with the same reference numeral, is different from FIG. 1 merely in that the organic EL devices 11 of the display unit 1 according to an embodiment are replaced by the micro LEDs 12. Such a display unit 1′ also produces an effect similar to that of the display unit 1.

The shape of the microlenses 41 in plan view is not limited to a circular shape described in the above-described embodiment. For example, as a result of adjacent ones of the microlenses 41 being provided across the entire sub-pixel through a process such as etch-back, the microlenses 41 may have the same rectangular shape or the like as the sub-pixel in plan view.

For high brightness and low power consumption, a so-called micro display including, as a light source, a micro LED, an organic EL device, or the like is required to be improved in usage efficiency of emitted light to enhance efficiency.

In this regard, JP 2021-136208 A describes that a semispherical microlens is disposed on a light-emitting device to enhance light-usage efficiency. Moreover, J P 2020-184481 A describes that a translucent layer is provided on a microlens to improve viewing angle characteristics.

A micro LED or an organic EL device is not so high in directionality of outputted light as a light source, so that light enters a microlens at various angles. Light entering at an angle equal to or greater than an optimal angle relative to an interface between a translucent layer and the microlens is fully reflected and thus cannot be externally extracted as an effective outputted light component, which causes a decrease in brightness.

A display unit according to an embodiment of the present invention enables a reduction in loss of outputted light of a micro LED or an organic EL device and improves usage efficiency.

A display unit according to a first aspect of the present invention includes a device substrate on which multiple light sources are disposed; a protective layer provided on the device substrate to cover the light sources; a color filter provided on the protective layer, the color filter including multiple monochromatic filters disposed corresponding to the light sources; a lens array provided on the color filter, the lens array including multiple microlenses disposed corresponding to the monochromatic filters; and a flattening layer provided on the lens array to cover the microlenses, the flattening layer having a refractive index lower than a refractive index of the microlenses.

In the display unit, a refractive index nₘ of the microlenses, a refractive index nₜ of the flattening layer, and a ratio r/H between a curvature radius r and a height H of a lens surface of the microlenses satisfy the following expression (1):

$$0.3 < ( {n}_{m} - {n}_{t} ) - 0.1 {( r / H )}^{2} + 0.2 ( r / H ) < 0.6 . \qquad ( 1 )$$

Obviously, numerous modifications and variations of the present invention are possible in light of the above teachings. It is therefore to be understood that within the scope of the appended claims, the invention may be practiced otherwise than as specifically described herein.

1. A display unit, comprising:
a device substrate;
a plurality of light sources positioned on the device substrate;
a protective layer formed on the device substrate such that the protective layer is covering the plurality of light sources;
a color filter formed on the protective layer and including a plurality of monochromatic filters positioned corresponding to the plurality of light sources, respectively;
a lens array formed on the color filter and including a plurality of microlenses positioned corresponding to the plurality of monochromatic filters of the color filter, respectively; and
a flattening layer formed on the lens array such that the flattening layer is covering the plurality of microlenses and has a refractive index that is lower than a refractive index of the plurality of microlenses,
wherein a ratio r/H between a curvature radius r and a height H of a lens surface of the plurality of microlenses satisfy 0.3<(nₘ−nₜ)−0.1(r/H)²+0.2(r/H)<0.6 where nₘ is the refractive index of the plurality of microlenses, and n, is the refractive index of the flattening layer.

2. The display unit according to claim 1, wherein r/H is 1 or greater and less than 2, and a difference between nₘ and nₜ is in a range of 0.2 to 0.5.

3. The display unit according to claim 1, wherein r/H is 2 or greater and less than 3, and a difference between nₘ and nₜ is in a range of 0.3 to 0.6.

4. The display unit according to claim 1, wherein r/H is 3 or greater, and a difference between nₘ and nₜ is in a range of 0.6 to 0.8.

5. A display unit, comprising:
a device substrate;
a plurality of light sources positioned on the device substrate;
a protective layer formed on the device substrate such that the protective layer is covering the plurality of light sources;
a color filter formed on the protective layer and including a plurality of monochromatic filters positioned corresponding to the plurality of light sources, respectively;
a lens array formed on the color filter and including a plurality of microlenses positioned corresponding to the plurality of monochromatic filters of the color filter, respectively; and
a flattening layer formed on the lens array such that the flattening layer is covering the plurality of microlenses and has a refractive index that is lower than a refractive index of the plurality of microlenses,
wherein a ratio r/H between a curvature radius r and a height H of a lens surface of the plurality of microlenses is 3 or greater, and a difference between a refractive index nₘ of the plurality of microlenses and a refractive index n, of the flattening layer is 0.3 or greater.

6. The display unit according to claim 1, wherein the plurality of light sources is a plurality of organic EL devices.

7. The display unit according to claim 2, wherein the plurality of light sources is a plurality of organic EL devices.

8. The display unit according to claim 3, wherein the plurality of light sources is a plurality of organic EL devices.

9. The display unit according to claim 4, wherein the plurality of light sources is a plurality of organic EL devices.

10. The display unit according to claim 5, wherein the plurality of light sources is a plurality of organic EL devices.

11. The display unit according to claim 1, wherein the plurality of light sources is a plurality of micro LEDs.

12. The display unit according to claim 2, wherein the plurality of light sources is a plurality of micro LEDs.

13. The display unit according to claim 3, wherein the plurality of light sources is a plurality of micro LEDs.

14. The display unit according to claim 4, wherein the plurality of light sources is a plurality of micro LEDs.

15. The display unit according to claim 5, wherein the plurality of light sources is a plurality of micro LEDs.
